(19) United States
(12) Patent Application Publication
(10) Pub. No.: US 2006/0139050 A1
(43) Pub. Date: Jun. 29, 2006

(54) Circuit for transmitting high frequency signals

(75) Inventor: Shou-Kuo Hsu, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/317,815

(22) Filed: Dec. 22, 2005

(30) Foreign Application Priority Data
Dec. 24, 2004 (TW) 93140463

(51) Int. Cl. H03K 17/16

(52) U.S. Cl. 326/30

(57) ABSTRACT

A transmission circuit for transmitting an IEEE 1394b signal includes a driving circuit, a load circuit connected to the driving circuit, a first signal line and a second signal line connected to the load circuit, an IEEE 1394b interface, a first resistor, a second resistor, and a third resistor. Two ends of the first resistor are separately connected between the first signal line and the second signal line. The second resistor is connected between one end of the first resistor and one terminal of the interface. The third resistor is connected between another end of the first resistor and another terminal of the interface. The third resistor is connected in series between the IEEE 1394b interface and the second signal line.

### BACKGROUND OF THE INVENTION

1. Field of the Invention

The present invention relates to transmission circuits, and particularly to a circuit for transmitting high frequency signals which can compensate impedance losses to decrease overshoot.

2. General Background

IEEE 1394 (also named FireWire by Apple) is a very fast external bus standard that supports data transfer rates of up to 400 Mbps (in 1394a) and 800 Mbps (in 1394b). IEEE 1394b is a new version of the IEEE 1394, with higher transmission frequency and longer transmission distance ability than IEEE 1394a. IEEE 1394b signal is one kind of high frequency signals.

A transmission circuit for transmitting the IEEE 1394b signal is generally fixed on a printed circuit board (PCB). In response to demands in the marketplace and the pressures of competition, better performing PCBs were sought. One improvement that was found involved the composition of the PCB. PCBs are composed of layers or fixing plates. The thinner the fixing plates of the PCB are, the better the electronic performance the PCB has, because line width and line distance of signal lines on a thinner fixing plate are less than on a thicker fixing plate. Previously a common specification for fixing plates was termed as 2116. Then another specification termed as 1080 came into use. Fixing plate 1080 is thinner than the fixing plate 2116. Fixing plate 1080 performs better in reducing crosstalk, flight times, and rise times than fixing plate 2116. Referring to FIG. 5, a conventional transmission circuit fixed on a PCB using fixing plates 1080 includes a driving circuit 201, a load circuit 202 connected to the driving circuit 201, a first signal line 203 and a second signal line 204 connected to the load circuit 202, and an IEEE 1394b interface 205 connected to the first and second signal lines 203 and 204. However, if the above circuit is used with a PCB using fixing plates 1080 then an impedance between a point a and a point b of the circuit is decreased. The impedance is reduced from 105 Ω to 100 Ω and no longer satisfies a predetermined impedance matching requirement of 110 Ω(+/−6 Ω). Thus, what is termed overshoot occurs in the PCB. This may cause a diode with protecting functions in the PCB to be damaged and the PCB to be disabled.

What is desired, therefore, is a transmission circuit which can compensate impedance losses to decrease overshoot.

### SUMMARY

In a preferred embodiment, a transmission circuit for transmitting an IEEE 1394b signal includes a driving circuit, a load circuit connected to the driving circuit, a first signal line and a second signal line connected to the load circuit, an IEEE 1394b interface, a first resistor, a second resistor, and a third resistor. Two ends of the first resistor are separately connected between the first signal line and the second signal line. The second resistor is connected between one end of the first resistor and one terminal of the interface. The third resistor is connected between another end of the first resistor and another terminal of the interface. The transmission circuit compensates impedance loss to decrease overshoot.

Other advantages and novel features will become more apparent from the following detailed description when taken in conjunction with the accompanying drawings, in which:

### BRIEF DESCRIPTION OF THE DRAWINGS

FIG. 1 is a circuit diagram of a circuit in accordance with a preferred embodiment of the present invention, for transmitting an IEEE 1394b signal;

FIG. 2 is an equivalent circuit diagram of an impedance between two terminals of an IEEE 1394b interface of the circuit of FIG. 1;

FIG. 3 is an equivalent circuit diagram of an impedance between two signal lines of the circuit of FIG. 1;

FIG. 4 is a graph of output waveforms from the circuit of FIG. 1, a conventional transmission circuit of FIG. 5, and a standard output waveform with no impedance compensation; and

FIG. 5 is the circuit diagram of a conventional signal transmission circuit.

### DETAILED DESCRIPTION OF THE EMBODIMENT

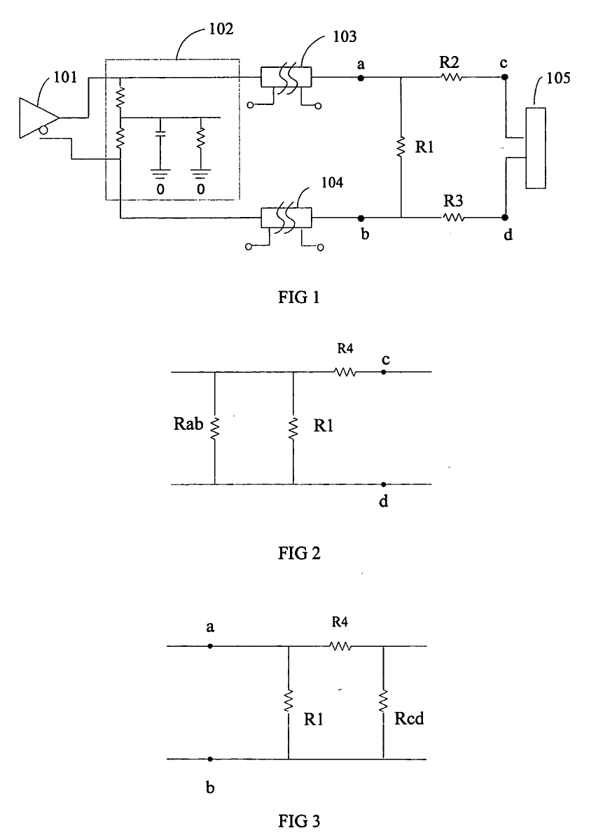

Referring to FIG. 1, a circuit for transmitting an IEEE 1394 b signal in accordance with a preferred embodiment of the present invention. One of various applications of the circuit is using a PCB comprised of fixing plates according to the specification 1080. Other applications using circuit boards with other specifications may also be implemented. The circuit includes a driving circuit 101, a load circuit 102, a first signal line 103, a second signal line 104, an IEEE 1394b interface 105, a first resistor R1, a second resistor R2, and a third resistor R3. The first resistor R1, the second resistor R2, and the third resistor R3 form an impedance compensator. The load circuit 102 is connected in series to the driving circuit 101. The first and the second signal lines 103 and 104 are connected to the load circuit 102. Two ends of the first resistor R1 are separately connected between the first signal line 103 and the second signal line 104. The second resistor R2 is connected between one end of the first resistor R1 and one terminal of the IEEE 1394b interface 105. The third resistor R3 is connected between the other end of the first resistor R1 and the other terminal of the IEEE 1394b interface 105.

An impedance between a point a of the first signal line 103 and a point b of the second signal line 104 is equal to that of a resistor Rab. An impedance between a point c and a point d of two terminals of the interface 105 is equal to that of a resistor Rcd. The resistors R2 and R3 are equal to an equivalent resistor R4.

Referring to FIG. 2, the resistor R1 and the resistor Rab are connected in parallel and then connected in series to the equivalent resistor R4. A first equation is concluded, Rcd=Rab*R1/(Rab+R1)+R4.

Referring to FIG. 3, the resistor R4 and the resistor Rcd are connected in series and then connected in parallel to the resistor R1. A second equation is concluded: Rab=(Rcd+R4)*R1/(Rcd+R1+R4).

In combining the first and the second equations, the following equations can be formulated: R1=Rab*Sqrt(Rcd/(Rcd−Rab))
R4=Sqrt(Rcd*(Rcd−Rab)).
For example when Rcd=110 Ω; Rab=100 Ω; R2=R3=R4/2, then

R1=332 Ω; R4=33 Ω;R2=R3=R4/2=16.5 Ω

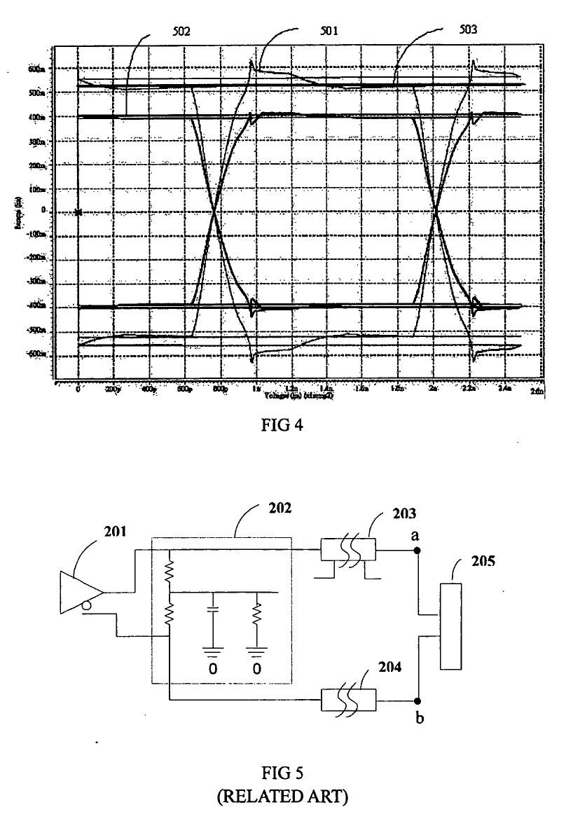

Referring to FIG. 4, a horizontal axis stands for time, and a vertical axis stands for output voltage of the transmission circuits. Waveform 503 represents a standard output waveform without impedance compensation. Waveform 501 depicts an output of the conventional transmission circuit of FIG. 5 but used on a PCB using fixing plates meeting the 1080 specification. Waveform 502 stands for an output waveform of the preferred embodiment of the present invention also using a PCB using fixing plates meeting the 1080 specification. A maximum voltage of the waveform 502 is much lower than that of the waveform 501. The graph clearly illustrates that overshoot is greatly decreased in the preferred embodiment of the present invention.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. A transmission circuit for transmitting a high frequency signal, the transmission circuit comprising:
a driving circuit;
a load circuit connected to the driving circuit;
an interface;
a pair of signal lines connecting the load circuit to the interface; and
an impedance compensator connected between the pair of signal lines and the interface.

2. The transmission circuit as claimed in claim 1, wherein the impedance compensator comprises a first resistor, a second resistor, and a third resistor.

3. The transmission circuit as claimed in claim 2, wherein a first end of the first resistor is connected to one of the signal lines and a first end of the second resistor, a second end of the first resistor is connected to another of the signal lines and a first end of the third resistor.

4. The transmission circuit as claimed in claim 3, wherein the interface comprises a pair of terminals separately connected to second ends of the second and third resistors.

5. The transmission circuit as claimed in claim 3, wherein an impedance between two terminals of the interface is equal to that of a resistor Rab, an impedance between the pair of signal lines is equal to that of a resistor Rcd, Rab=(Rcd+R2+R3)*R1(Rcd+R2+R3), and Rcd=Rab*R1/(Rab+R1)+R2+R3.

6. The transmission circuit as claimed in claim 4, wherein the resistance of the second resistor is equal to the third resistor.

7. The transmission circuit as claimed in claim 6, wherein
R1=Rab*Sqrt(Rcd/Rcd−Rab), and R2=R3=Sqrt(Rcd−Rab)*Rcd/2.

8. A transmission circuit for transmitting an IEEE 1394b signal, the transmission circuit comprising:
a driving circuit;
a load circuit connected to the driving circuit;
a pair of signal lines connected to the load circuit;
an IEEE 1394b interface comprising a pair of terminals;
a first resistor with its two ends separately connected to the pair of signal lines;
a second resistor with its two ends separately connected to one end of the first resistor and one terminal of the interface; and
a third resistor with its two ends separately connected to the other end of the first resistor and the other terminal of the interface.

9. The transmission circuit as claimed in claim 8, wherein an impedance between two terminals of the IEEE 1394b interface is equal to that of a resistor Rab, an impedance between the pair of signal lines is equal to that of a resistor Rcd, Rab=(Rcd+R2+R3)*R1 (Rcd+R2+R3), and Rcd=Rab*R1/(Rab+R1)+R2+R3.

10. The transmission circuit as claimed in claim 9, wherein the resistance of the second resistor is equal to the third resistor.

11. The transmission circuit as claimed in claim 10, wherein:
R1=Rab*Sqrt(Rcd/Rcd−Rab), and R2=R3=Sqrt(Rcd−Rab)*Rcd/2.

12. A circuit for transmitting high frequency signals of an electrically connectable interface, comprising:
an interface electrically connectable therewith to provide high frequency signals;
a driving and load circuit signal-communicable with said interface when said driving and load circuit is electrically connected with said interface;
at least two signal lines electrically connectable between said interface and said driving and load circuit respectively so as to transmit said high frequency signals therebetween; and
an impedance compensator electrically connectable between said at least two signal lines and said interface so as to compensate impedance between said at least two signal lines.

13. The circuit as claimed in claim 12, wherein said impedance compensator comprises at least one parallel-arranged resistor and at least one serial-arranged resistor.
